(19) United States
(12) Patent Application Publication
(10) Pub. No.: US 2017/0199261 A1
(43) Pub. Date: Jul. 13, 2017

(54) METHOD FOR ASSESSING AND IMPROVING DATA QUALITY IN FINE STRUCTURE ANALYSIS DATA

(71) Applicant: Acuitas Medical Limited, Swansea (SW) (GB)

(72) Inventors: Lance W. FARR, Swansea (GB); J. Michael BRADY, Oxford (GB); James RAFFERTY, Godrergraig (GB); Samantha Anne TELFER, Swansea (GB)

(21) Appl. No.: 15/315,112

(22) PCT Filed: May 30, 2015
(86) PCT No.: PCT/IB2015/054110

§ 371 Date: Nov. 30, 2016

Related U.S. Application Data
(60) Provisional application No. 62/005,292, filed on May 30, 2014.

(51) Int. Cl. G01R 33/565; G01R 33/483

(52) U.S. Cl. CPC G01R 33/56509; G01R 33/4833

(57) ABSTRACT

A method of improving the data quality in spatial frequency spectra by acquiring a prism acquisition consisting of echo data that is one or more repetitions of a one-dimensional frequency encoded signal along the length of one or more prism volumes, placed within a sample of a structure to be studied, generating prism profiles from the echo data, and correcting for motion during the acquisition by calculating motion having occurred during the prism acquisition from assessment of the prism profiles for the multiple repetitions, or by indicating a region of sample of structure to be studied on a reference image, using this to segment a map of features in the prism profiles and shifting the location of this region to correct for motion having occurred between the acquisition of the reference image and the prism acquisition.

### CROSS-REFERENCE TO RELATED APPLICATIONS

This application claims the benefit of U.S. Provisional Patent Application No. 62/005,292 filed May 30, 2014.

### BACKGROUND OF THE INVENTION

1. Field of the Invention

The present invention relates to the field of fine structures characterized by magnetic resonance and to a method for processing magnetic resonance signals.

2. Prior Art

U.S. Pat. No. 7,932,720 describes a method for measurement of biologic textures too fine to be resolved by conventional magnetic resonance imaging, providing a quantitative measure of the characteristic spatial wavelengths of these textures. In its simplest form the method consists of acquiring finely-sampled spatially-encoded magnetic resonance echoes along an axis of a selectively-excited inner-volume positioned within the biologic tissue to be analyzed. Signal analysis yields spectra of textural wavelengths within various sub-regions along the spatially encoded axis of the selected tissue volume.

PCT Publication No. WO 2013/086218 describes a method for linear analysis of data acquired as per U.S. Pat. No. 7,932,720, in which the data analysis is performed using linear filtering processes. These processes allow the signal-to-noise, error-bars and confidence intervals in the resulting structural frequency spectra to be readily quantified.

While the approaches detailed in the prior art enable spatial frequency spectra to be derived, and enable the uncertainty in these spectra to be quantified, they do not provide for methods to use this information to improve data quality, or indicate data quality to the user.

One significant advantage of the methods detailed in the prior art above is that the resulting spatial frequency spectra can be used to characterize finer structures than can be characterized by standard MR imaging techniques. However, this potentially makes these methods more susceptible to problems caused by patient motion. Motion correction in MR imaging typically involves attempting to minimize patient motion occurring, and acquisition of separate data, such as navigators, to quantify the motion at the same time as gathering the MR image itself, due to the relatively large number of phase encoding steps required for a standard MRI image, which typically results in a significant increase in scan time [C. Malamateniou, S. J. Malik, S. J. Counsell, J. M. Allsop, A. K. McGuinness, T. Hayata, K. Broadhouse, R. G. Nunes, A. M. Ederies, J. V. Hajnal and M. A. Rutherford. “Motion-Compensation Techniques in Neonatal and Fetal MR Imaging”. American Journal of Neuroradiology (2013) Vol 34, pp 1124-1136.].

Typically, when recording data on an MRI system, multiple receiver coils are used to record the magnetic resonance echo signal. Directly measuring the noise measured by each receiver coil during an MRI acquisition has been proposed as far back as 1990 (P. B. Roemer, W. A. Edelstein, C. E. Hayes, S. P. Souza and O. M. Mueller. “The NMR Phased Array”. Magnetic resonance in Medicine. 16. pp 192-225 (1990)).

When combining data from multiple receivers, for example in radio system design, there are a number of potential methods to combine the signals from the multiple receivers, termed diversity combining techniques. Some commonly used techniques include equal gain combining, maximal-ratio combining, switched combining and selection combining [Brennan, D. G., “Linear diversity combining techniques,” Proceedings of the IEEE, vol. 91, no. 2, pp. 331, 356, February 2003].

Local cross-correlations are typically used to calculate the relative shift or delay between signals in fields such as seismology [D. Hale. “An efficient method for computing local cross-correlations of multi-dimensional signals”. SEG Technical Program Expanded Abstracts 01/2006; 25(1)] and space science [G. H. Fisher and B. T. Welsch. “FLCT: A Fast, Efficient Method for Performing Local Correlation Tracking”. Subsurface and Atmospheric Influences on Solar Activity ASP Conference Series. (2008). Vol 383, pp 373-380] where the shift in an image may not be constant across the whole of the field of view of the image.

Both magnitude and phase images have been used, both individually and together, for feature extraction in MR images (P. Bourgeat, J. Fripp, P. Stanwell, S. Ramadan and S. Ourselin. “MR image segmentation of the knee bone using phase information”. Medical Image Analysis. Vol 11. (2007). pp 325-335).

### BRIEF DESCRIPTION OF THE DRAWINGS

FIG. 1 shows prism profiles from three different receiver coils from the same prism acquisition containing multiple prism volumes, with comparatively low, medium and high signal to noise ratio (SNR).

FIG. 2 shows an example of 6 frames derived from a liver prism acquisition. Motion is clearly visible when comparing the anatomical features to the three markers (black circles) indicating the same pixel locations on each of the frames.

FIG. 3 shows two prism profile plots from single-prism volumes, illustrating the changing prism profile magnitude versus time. The plots show (a) little visible motion in one, and (b) significant visible motion in the other.

FIG. 4 is an illustration of one method of calculating the local cross correlation for one sub-region for one pair of frames. Translating the sub-region across the two frames allows a set of local shifts to estimated.

FIG. 5 is an example of two plots of the calculated local motion values plotted as a gray-scale color at each point. The point is plotted at the center of the sub-region used, the gray outer border being due to the size of this sub-region.

FIG. 6 is an illustration of one method of calculating the optimal shift to apply to a region of interest when segmenting data from a prism acquisition.

### DETAILED DESCRIPTION OF THE PREFERRED EMBODIMENTS

The following terms will be used throughout the text:

Prism Acquisition: The full acquisition of echo data from a set of prism volumes recorded for a number of repetitions for a number of receiver coils.

Echo Data: The digitized recording of the MR echo signal recorded on a set of receiver coils from a set of prism volumes. A single MR echo is recorded for each repetition, each receiver coil and each prism volume.

Prism Volumes: The physical location(s) in the sample of the structure to be studied from which the echo data is generated. A prism volume may have any arbitrary cross-sectional shape, although it is generally rectangular in cross-section.

Prism profile: The transform of the echo data which gives the signal versus position along a given prism volume for each receiver coil and each repetition. This gives an estimate of the variation of signal-generating material versus position along each of the prism volumes.

Receiver Coils: The RF receiver coils which are used to record the echo data comprising the prism acquisition.

Spatial Frequency Spectra: The frequency spectra which are produced following analysis of prism acquisition echo data as per the analysis methods such as disclosed in U.S. Pat. No. 7,932,720 and PCT Publication No. WO 2013/086218.

Repetitions: One or more repeated recordings of MR echo signals from the prism volumes. Multiple repetitions are performed in order that the signals can be averaged during the calculation of spatial frequency spectra in order to increase the signal-to-noise ratio in the spatial frequency spectra.

Study: A number of scans performed sequentially during which the patient is nominally in the same location in the scanner such that the reference images and prism acquisitions can be co-located with one another.

Reference Image: An MR image acquired in the same study as a prism acquisition which is used both to position the prism acquisition, and also on which a region of the sample of the structure to be studied is indicated, by denoting the periphery of a tissue of interest, or structure of interest.

Region/Region of Interest: This is the portion of the sample of the structure of interest which is under study, and in which the prism acquisition has been acquired.

Noise data: Noise measured on the same set of Magnetic Resonance Imaging (MRI) System receiver coils used for the prism acquisition itself.

Block of repetitions: A number of one or more temporally adjacent repetitions which are combined in order that the signal-to-noise ratio is potentially higher than for a single repetition, but fewer than the total number of repetitions acquired so that there are multiple blocks for one prism acquisition.

Frame: A plot of the prism profiles for a set of adjacent prism volumes for a block of repetitions.

Sub-region: A spatial portion of a frame chosen based upon the expected scale of local motion in the sample of the structure to be studied.

This disclosure details a method for improving the quality of spatial frequency spectra calculated from a prism acquisition gathered using an MRI system, according to the methods described in U.S. Pat. No. 7,932,720 and PCT Publication No. WO 2013/086215. The prism volumes forming the prism acquisition are placed within a sample of a structure to be studied.

When radiologists and radiographers are presented with a poor image in standard MRI imaging, they are trained in recognizing artifacts in the data and are able to interpret or re-acquire the data as appropriate. Poor images may be caused by low signal-to-noise ratio, motion of the patient, blood flow, aliasing, and chemical shift to name but a few sources.

Prism acquisition echo data, and the associated spatial frequency spectra are not directly interpretable by a clinician in the same way as a regular MRI image. For this reason it is desirable to process the prism acquisition echo data prior to analysis, so that the data quality can be either manually or automatically assessed, prior to analysis. Ideally this will occur during or immediately following the acquisition (a scan), while the patient is still in the scanner, so that a poor prism acquisition can be reacquired correctly. For artifacts which can be corrected for in post-processing, it is also desirable to correct these prior to generation of the spatial frequency spectra.

Depending upon the quality of the prism acquisition echo data, it may be necessary to:
Throw away the data completely and re-acquire it.
Warn the user (radiologist or radiographer) of poor quality data, but still allow it to be analyzed.
Process good quality data.

### Signal-to-Noise Ratio (SNR) Assessment

In a preferred embodiment of the invention, it is important to be able to assess the SNR of a prism acquisition for a number of reasons:

1. It allows datasets (prism acquisitions) with an overall SNR below a threshold value to be identified and either discarded or indicated to the user.

2. In MRI systems with multiple receiver coils, it may be beneficial to only use coils with an SNR above a threshold value. Using only coils with an SNR above this threshold may improve the analysis results over using all coils.

3. Further to point (2), some diversity combining techniques used to combine data from multiple receiver coils use an estimate of the SNR in order to combine the signals from each coil.

In order to develop an estimate of the SNR, it is necessary to have an estimate of both the signal and the noise, in order to calculate the ratio between these quantities. The measure of signal can be readily derived from the prism acquisition echo data itself. The prism acquisition echo data generally consists of echo data from a set of prism volumes for multiple repetitions of the prism acquisition, the multiple repetitions being performed in order to increase the SNR in the final signal due to signal averaging in post-processing. In one preferred embodiment the measure of signal would be performed by measuring the peak of the center of the echo signal for each receiver coil. In another preferred embodiment this would be performed by Fourier transforming the prism acquisition echo data to generate a prism profile (prism signal versus position along the prism) and using this to estimate the signal-versus-position along the length of the prism volume for each coil.

A number of methods of deriving an estimate of the noise data exist. In one preferred embodiment, a direct measure of the noise can be performed, and this direct measurement can be performed at a number of possible times relative to the prism acquisition. In one preferred embodiment, the measure of noise cart be performed immediately following the acquisition of the prism acquisition echo data, by acquiring further data on each of the receiver coils used for the prism acquisition. In an alternative preferred embodiment, this noise data acquisition would be performed immediately before the prism acquisition. In order to perform a direct measurement of the noise, in one preferred embodiment the radio frequency amplifiers for each of the receiver coils are blanked. In another preferred embodiment a further repetition of the prism acquisition is performed, but with the radio frequency transmit voltages set to zero.

As the prism acquisition generally consists of multiple repetitions of echo data, performed in order to increase the SNR in the final signal due to signal averaging in post-processing, in yet another preferred embodiment, the measure of noise data would be performed at one or more time points between the repetitions of the prism acquisition echo data. Another method of deriving an estimate of the noise is to calculate the statistics of the noise contribution as per the method described in PCT Publication No. WO 2013/086218, where the noise statistics are inferred from the scatter of the multiple repetitions of the prism acquisition echo data.

As the prism acquisition echo data (prism echo data) includes data at all k-space points, the SNR can be assessed at any, or all, of these k-space points. Selecting a range of k-space values over which to perform the SNR assessment may be desirable depending upon the use of the calculated SNR value. If the SNR value is to be used to give an indication of the quality of the output spatial frequency spectrum (spectrum), then assessing the range of k-values in the displayed output spatial frequency spectrum (spectrum) is probably the most appropriate. If, alternatively, the SNR value is to be used to enable signals from a set of receiver coils (coils) to be combined in a more optimal way, for example by correcting for the phase variation along each prism profile, then calculating the SNR at the low k-space values could be more appropriate. This embodiment actually gives an estimate of more than the direct noise data measure, as this measure will capture the uncertainty in the spectrum from all sources: receiver coil noise, motion, etc. . . . . The output of this can be used to calculate an estimate of the noise level in the data, and also a set of “confidence intervals”.

The quotient of the signal and corresponding noise values are then used to calculate an estimate of the SNR for each receiver coil.

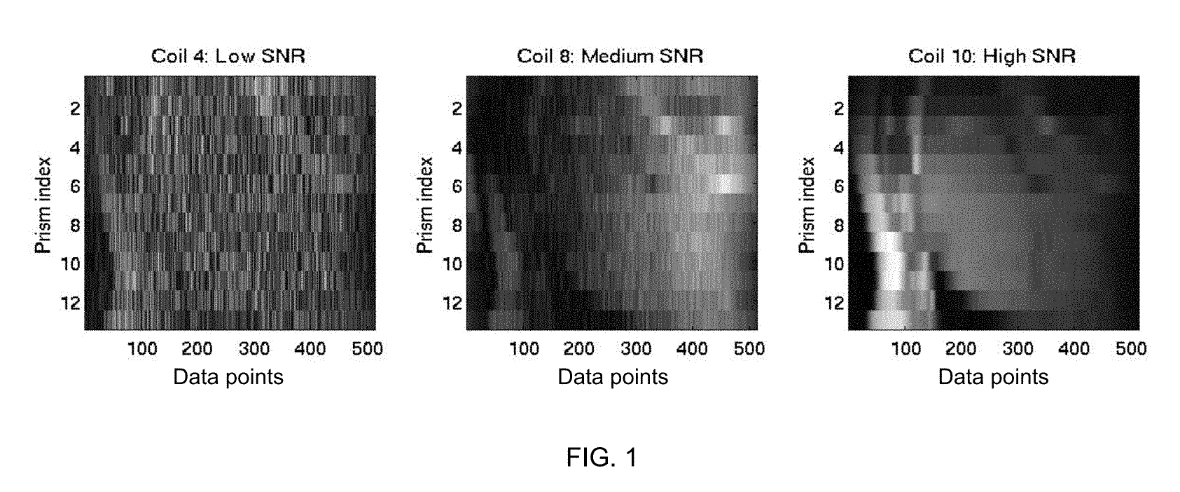

An illustration of the magnitude of the prism profiles (the Fourier transform of the measured prism acquisition echo data for each prism volume) for three example coils with low, medium and high SNR is given in FIG. 1.

The calculation of SNR for each receiver coil can then be used to combine the signal from the coils in order to maximize the SNR in the combined data. This can be performed using a number of diversity combining techniques. In one embodiment this is performed by using Maximal Ratio Combining to weight each of the receiver coils with respect to their SNR and then they are combined, by summing or averaging them together. In another embodiment this is performed by Selection Combining where a number of the coils with the highest SNR values are chosen and combined, rather than using all of the coils. The number of coils chosen depends upon the calculated SNR values—for example the top 10% of coils may be chosen, or all coils with an SNR above a certain threshold value.

As detailed in U.S. Pat. No. 7,903,251 and U.S. Pat. No. 8,462,346, one possible method for displaying spatial frequency spectra generated from the prism acquisition echo data is as a signal map. When displaying this signal map to the user, it is possible to display alongside this a map generated from the mean noise or one of the confidence interval lines as calculated above called a noise map. This can then be either interpreted alongside the signal map, or some measure can be extracted from this (such as the mean RGB intensity level) which can be used to indicate which regions of the signal map are above this. This could be used to identify those regions of the signal map with SNR above some threshold value and only display those regions.

Another alternative method of assessing the SNR level in the data is to count the number of points above either the mean noise level or one or more of the confidence interval (CI) levels, over some range of spatial frequencies of interest. The advantage is that this gives an estimate of the SNR level at the higher k-space values, which may be the values more indicative of disease in the tissue of interest.

### Motion Assessment—Motion During Data Acquisition

In general, MRI data acquisition for a given scan, whether an imaging scan or a prism acquisition (scan), can take from a few seconds to a number of minutes. Since only a subset of the full set of k-space values need to be acquired, prism acquisitions (scans) generally allow for faster data acquisition than regular image acquisitions. However, patient motion during a prism acquisition (scan) can still be a significant concern, since a significant advantage of this technique is the improved spatial resolution compared to standard MRI imaging sequences. For this reason, techniques for assessing and/or correcting for motion in prism acquisitions are desirable.

As mentioned previously, as a standard image is not routinely generated from prism acquisition echo data, it is harder for the user to manually assess the motion in the acquired data. For this reason it is necessary to either present the user with some visualization of the data which allows the motion to be manually assessed, and/or automate the assessment of motion in the data.

As the raw data for each repetition of the prism acquisition echo data is saved individually, it is possible to view and assess the prism profiles over time during a prism acquisition. Generally the prism profiles from a single repetition (measurement) may have too low SNR to visualize on its own. However, combining multiple temporally adjacent repetitions (termed “blocks” of repetitions), e.g.: by averaging, allows prism profiles to be generated which have sufficient SNR to allow anatomical features to be distinguished. Comparing prism profiles generated from different blocks, for example subsequent blocks, allows the relative motion of these anatomical features to be assessed, quantified and corrected for.

One method of performing this is to generate a series of prism profiles for each block, the plot of the prism profiles for a given block being termed a frame. Each frame can be generated from multiple adjacent blocks of repetitions: for example, block 1 could be derived from repetitions 1-5, block 2 from repetitions 6-10, etc. . . . . Alternatively, the subsequent frames could be generated from overlapping blocks of repetitions: for example block 1 from repetitions 1-5, block 2 from repetitions 2-6, etc. . . . . Motion between the blocks can then be easily visualized or assessed. The calculated motion can then be compared to a threshold value. If the motion is above this threshold value then the prism acquisition could be indicated to the user for re-acquisition.

As described previously, in one embodiment, the motion can be assessed manually. In an alternative embodiment, the assessment of motion can be automated. Some embodiments are more suited to prism acquisition echo data which is acquired from multiple adjacent prism volumes, and other embodiments are more suited to prism acquisition echo data which is acquired from a single prism volume.

### Multiple Prism Volume Data

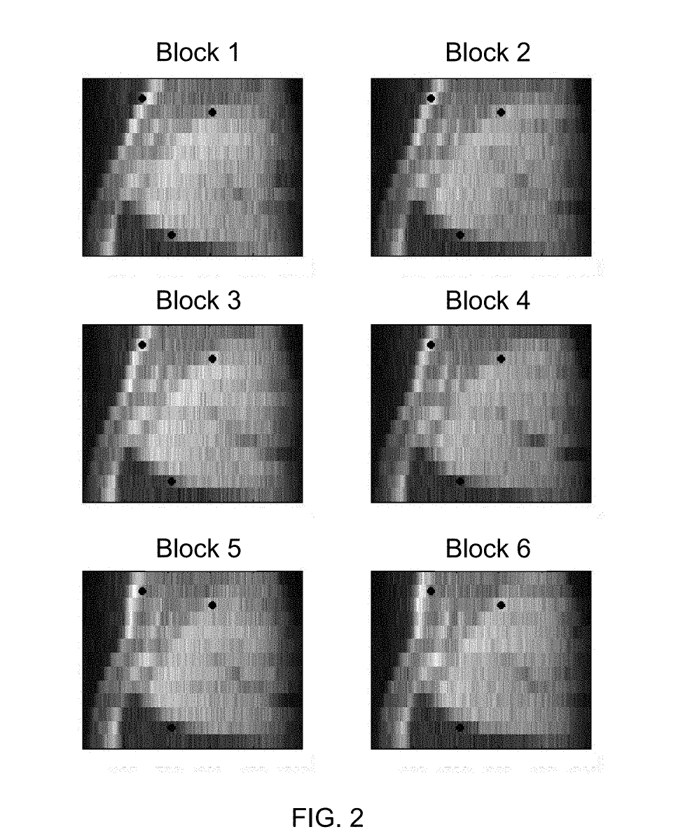

An example of a method of visualizing the motion in a prism acquisition containing multiple prism volumes can be seen in FIG. 2. In this embodiment, in order to visualize the motion, subsequent frames of the animation are shown as separate plots, with marker points indicating the position of anatomically significant features from the first block of repetitions. In an alternative embodiment, these frames are viewed as an animation.

In some applications, such as prism acquisition echo data acquired in the liver, visual inspection of representative examples of liver prism acquisitions indicate that various types of motion are present in liver data, including overall translations in the plane of prisms, and stretching/squashing.

Therefore, in an alternative embodiment, a method of quantifying the degree of this type of motion is detailed. This is performed by calculating the local cross-correlation: that is, compute the 2-dimensional cross-correlation on a localized area of two of the frames, and repeat this across the frames. This embodiment attempts to calculate the relative shift of different regions of the frames relative to each other. One possible method of achieving this is shown below, although there are other ways to calculate this.

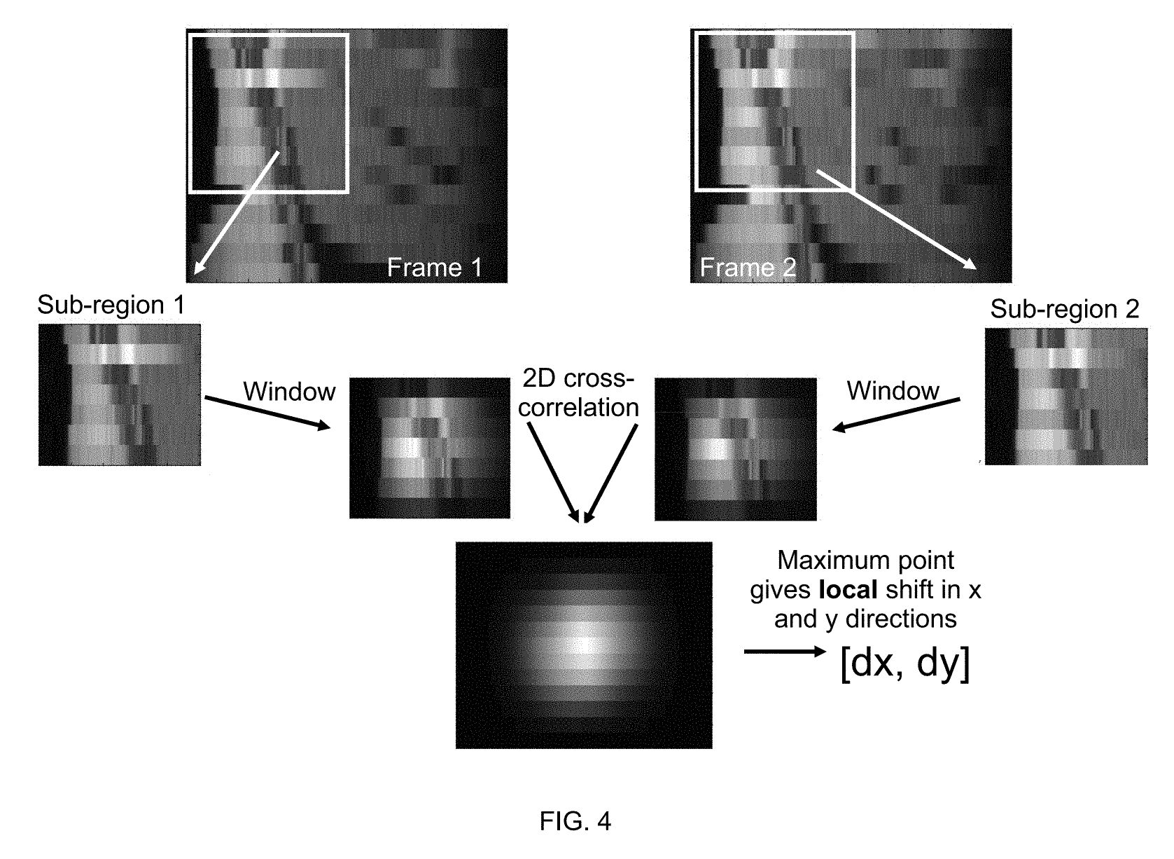

FIG. 4 illustrates a method for calculating the local cross-correlation between two frames. Each of these frames has been generated by calculating the prism profile magnitudes for each prism volume and displaying them as a gray-scale intensity plot. A sub-region of each of these frames is then taken, the size of this sub-region is chosen appropriately depending upon the local variation in motion typical in that tissue. If motion is very localized, then a small sub-region is chosen; conversely if the motion is generally quite widespread, then a larger sub-region is chosen. The two sub-regions are then windowed and the 2D cross correlation is calculated. The position of the maximum value of the computed cross correlation gives the estimated local shift in x- and y-position between the two sub-regions. The sub-regions are then translated across and down the frames in steps of one or more pixels, and the same process is repeated at each step, thus building up a map of the magnitude and direction of the local shift versus position, termed a shift map. Pre-processing of the frames, for example smoothing, may be desirable in order to remove some of the noise in the frames, making the results more robust.

The preferred embodiment described above is limited in the fact that it can only determine whole-pixel shifts. However, the cross-correlation theorem states that the cross correlation of two functions f(t) and g(t) can be expressed as:

$$f * g = {\int }_{- ∞}^{∞} \overline{f} ( T ) g ( t + T ) dT = {\int }_{- ∞}^{∞} \overline{F} ( v ) G ( v ) {e}^{- 2 π ivt} dv$$

Thus, instead of performing the cross-correlation calculation in position-space, as described above, performing it in frequency-space instead allows t to be freely chosen. This allows the cross-correlation for sub-pixel shifts to be calculated.

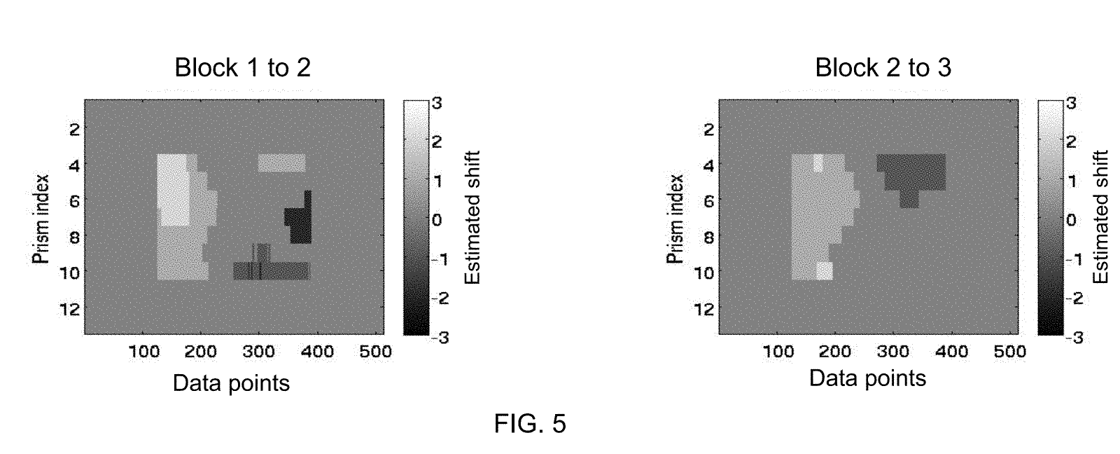

The estimates of local motion as calculated in the preferred embodiments above can then be used in a number of ways. In one embodiment the calculated shifts are compared to a threshold value, and if any local shifts between adjacent frames exceed this, then the prism acquisition is indicated to the user as having significant motion, so that the prism acquisition may be reacquired while the patient is still in the scanner, if necessary. In an alternative embodiment, the estimates of local motion for each pair of frames are displayed to the user as an animation or series of plots so that the local motion can be assessed manually. An example of this is given in FIG. 5. For example, the magnitude of the local shift could be encoded as the value/brightness at that point in the plot, and the direction of the motion could be encoded as a different color/hue. Alternatively different shifts can be encoded as different gray-scale colors as shown in FIG. 5.

In one embodiment, the assessment of motion in the prism acquisition, as calculated in the embodiments above, can be used to spatially shift the position of the frames relative to one another prior to generation of spatial frequency spectra, in order to correct for the motion having occurred between those frames.

### Single Prism Volume Data

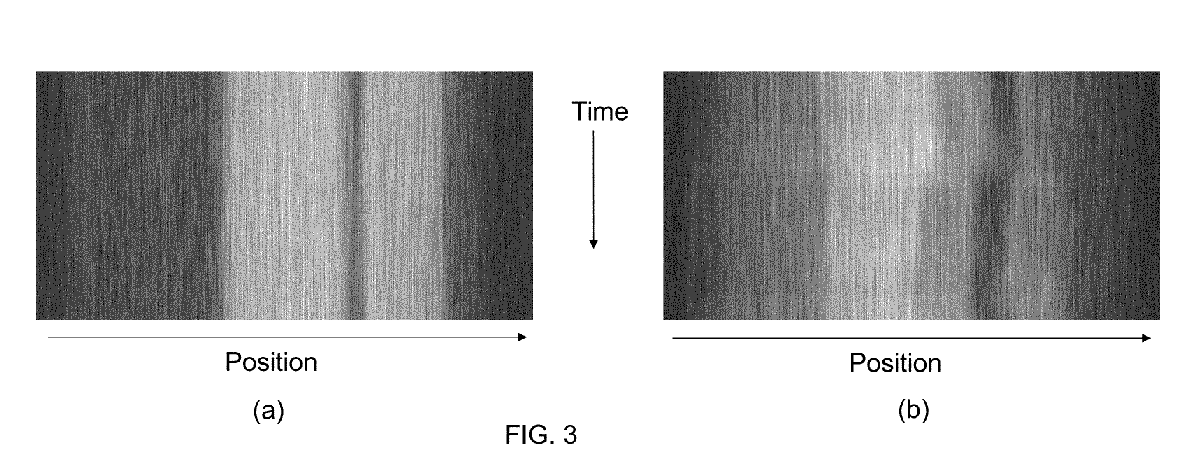

As stated above, in some applications, prism acquisition echo data is acquired for a single prism volume, rather than an array of prism volumes. In this case, the data can still be visualized as series of frames or an animation in the same way as multiple-prism-volume data, or the local cross-correlation (in this case local 1D cross correlation) can still be calculated. However, this data can also be visualized by displaying each single-prism frame side-by-side in one plot. Two examples of this for prism acquisitions acquired in the human brain are shown in FIG. 3, for (a) very little patient motion, and (b) significant patient motion. As already discussed above, these plots can be calculated from multiple overlapping blocks of repetitions, which can help them appear smoother and make them easier to interpret.

### Motion Assessment—Motion Between Reference Image Acquisition and Prism Acquisition

Due to the nature of the data acquisition, prisms can extend outside the sample of structure to be studied (tissue of interest). Therefore, it is sometimes necessary to determine which region(s) of the prism profiles should be analyzed and which should be ignored. Although it is possible to do this to some extent using the prism profiles discussed above, the pixel size in these is generally highly anisotropic, which makes it hard for some anatomical features to be identified. For this reason it is sometimes desirable to be able to co-locate the locations of the acquired prism volumes with one or more separate reference images also gathered in the same scanning session, enabling anatomy to be co-located between the reference image and prism acquisition. In this case, co-location could be desirable in order to indicate the positions of the prism volumes on the reference image, and more importantly so that the organ (or region) to be analyzed can be specified on the reference image—for example by manually indicating the border of the region or automatically segmenting the region—and this could then be used to segment the prism profiles during analysis.

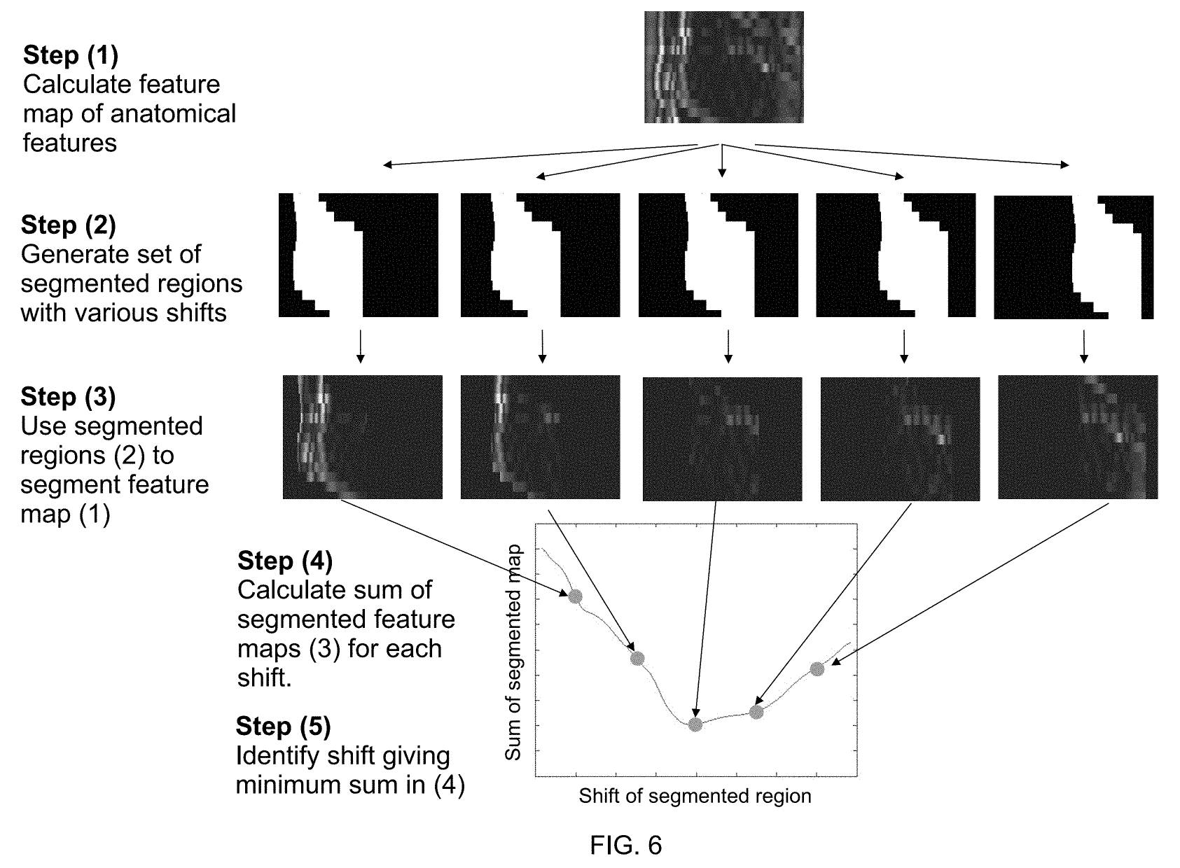

However, there is sometimes significant motion between a reference image acquisition and a prism acquisition. This is especially true in applications such as the liver, where a reference image acquisition and a prism acquisition will be acquired on separate breath-holds. Between subsequent breath holds, the diaphragm, and thus the other internal organs including the liver, may not be in exactly the same location for both of the breath holds. As such, it may be desirable to use a reference image to determine an initial segmentation, and then to refine (fine-tune) the segmented region to correct for any gross motion which has occurred between the reference image acquisition and prism acquisition. An example of one method of performing this is detailed in FIG. 6.

As in the previous embodiments, the SNR is used to combine prism acquisition echo data from multiple receiver coils. In one embodiment this is used to discard receiver coils with a low SNR. In an alternative embodiment the SNR is used to weight the receiver coil signals prior to combination. The prism profiles are then calculated, and a feature map is then generated from the prism profiles, identifying regions where boundaries between tissues occur. In one preferred embodiment, spatial smoothing is performed along the axis of each of the prism profiles prior to generation of the feature map, in order that a lot of the noise is suppressed in the data while retaining the significant anatomical features, which serves to improve the performance of the feature map generation. In one of the preferred embodiments the feature map is generated by calculating the numerical gradient of the prism profiles. In another embodiment the feature map is calculated using Canny edge detection. In another embodiment the feature map is calculated by application of a Sobel filter.

An anatomical region of interest (ROI) is then identified on the reference image discussed earlier. This may be performed manually, for example by drawing the outline around a vertebra if performing a spine acquisition, or around the liver if performing a liver acquisition. Alternatively this may be performed by automated segmentation of the ROI from the reference image.

A coordinate transform is then used to translate this ROI from a set of points outlining the anatomy of interest in the reference image, to a set of points outlining the anatomy of interest in the feature map. These points are then used to perform an initial segmentation of the feature map.

In order to correct for motion which has occurred between the reference image and the prism acquisition, the set of points outlining the anatomy of interest in the segmented feature map may need to be translated, primarily along the length of the prisms. In order to calculate the optimal shift of the region of interest, a set of shifted ROIs are calculated, and each one is used to generate a segmented feature map. The segmented feature map containing the fewest features, especially around its periphery, is most likely to be the one with the optimal shift, as this will have the fewest boundaries between tissues within the ROI, and thus the ROI is likely to encompass homogeneous tissue.

In order to automate the selection of the refined ROI, a measure is extracted from the set of segmented feature maps. In one embodiment, this measure is the sum of the values in each of the segmented feature maps. In another preferred embodiment, it is the maximum value in each of the segmented feature maps.

The optimal shift is determined by identifying (estimating) the shift which minimizes the calculated measure.

While certain preferred embodiments of the present invention have been disclosed and described herein for purposes of illustration and not for purposes of limitation, it will be understood by those skilled in the art that various changes in form and detail may be made therein without departing from the scope of the invention as defined in the claims.

What is claimed is:

1. In a Magnetic Resonance Imaging (MRI) System, a method for improving the quality of spatial frequency spectra generated from a prism acquisition consisting of echo data that is one or more repetitions of a one-dimensional frequency encoded signal along the length of one or more prism volumes, placed within a sample of a structure to be studied, comprising;
a) gathering a prism acquisition consisting of one or more individual repetitions of echo data from one or more prism volumes using one or more receiver coils in the Magnetic resonance Imaging (MRI) System;
b) correcting for patient motion affecting the quality of the prism acquisition by:
i) transforming the echo data gathered in (a) for each prism volume to calculate the variation of signal versus position, termed the prism profile, for each repetition for each receiver coil;
ii) combining the prism profile from a selection of one or more of the receiver coils to produce a combined prism profile for each prism volume and each repetition;
iii) combining the repetitions gathered into blocks of one or more overlapping or adjacent repetitions to produce a series of frames showing the prism profiles for the set of prisms volumes for each block, and using the change in prism profiles between frames to calculate the patient motion which has occurred during the prism acquisition;
iv) using the calculation of patient motion in (iii) to determine whether the calculated motion is below a threshold value, and if so then calculating the spatial frequency spectra from the prism profiles, and if not then the dataset is discarded and indicated to be re-acquired;
or:
c) correcting for patient motion affecting the quality of the prism acquisition by:
i) during the same study, acquiring a reference image of the sample of the structure to be studied, either prior to or following the prism acquisition in (a), which is co-located with the prism acquisition in (a);
ii) specifying one or more regions of the sample of the structure to be studied on the reference image acquired in (c)(i);
iii) using a three-dimensional coordinate transform to translate the points specifying the regions in (c)(ii) from locations in the reference image to corresponding locations in the prism volumes;
iv) transforming the echo data gathered in (a) to calculate the signal versus position along each of the prism volumes for each repetition for each receiver coil, and for each prism volume to obtain the respective prism profile;
v) smoothing the prism profiles by application of a spatial filter in order to reduce the noise;
vi) calculating the presence of anatomical features in the prism profiles by generating a map of the prevalence of sharp boundaries and features present, termed the feature map;
vii) using the points calculated in (iii) to perform a segmentation of the feature map calculated in (vi) within the specified region;
viii) calculating the estimated shift of the segmented feature map in (vii) which minimizes the presence of anatomical features present in the segmented prism volumes, and using the estimated shift to spatially shift the segmented prism volumes to correct for motion, prior to generation of spatial frequency spectra from the prism acquisition echo data.

2. The method of claim 1 wherein the estimate of motion in (b)(iii) is used to correct for the motion which has occurred during the prism acquisition by spatially shifting the repetitions of prism profiles relative to one another in (b)(iv) prior to generation of spatial frequency spectra.

3. The method of claim 1 wherein the motion assessment in (b)(iii) is performed by generating plots of the prism profiles for each block, and displaying these as a series of frames, or animation, from which the user can visualize and assess the motion during the prism acquisition.

4. The method of claim 1 wherein the motion assessment in (b)(iii) is performed for one prism volume by generating plots of the prism profile for that prism volume for each block, and displaying each of these frames adjacent to one another to form one representation enabling the motion during the prism acquisition to be visualized.

5. The method of claim 1 wherein in (c), the calculation of the presence of anatomical features in (c)(vi) is performed by calculating a numerical gradient of the profile.

6. The method of claim 1 wherein in (c), the calculation of the presence of anatomical features in (c)(vi) is performed by using a Canny edge detection algorithm.

7. The method of claim 1 wherein in (c), the calculation of the presence of anatomical features in (c)(vi) is performed by application of a Sobel filter.

8. The method of claim 1 wherein in (b)(ii), the receiver coils are combined by:
d) measuring noise data on a set of receiver coils corresponding to the receiver coils used for the prism acquisition in (a);
e) estimating the signal-to-noise ratio (SNR) for each of the receiver coils using the ratio of the prism acquisition echo data acquired in (a) and the noise data acquired in (d) and using the ratio to combine the prism acquisition echo data from receiver coils using diversity combining in order to maximize the final SNR;
f) using the calculation of signal-to-noise ratio for each receiver coil in (b)(ii) to determine whether the prism acquisition has an SNR above a threshold value, and if not then the dataset is discarded and indicated to be re-acquired.

9. The method of claim 8 wherein the measurement of noise data in (d) is performed by blanking the radio frequency amplifiers for each of the receiver coils so that only noise data is gathered.

10. The method of claim 8 wherein the measurement of noise data in (d) is performed by setting the radio frequency transmit voltages to zero so that only noise data is gathered.

11. The method of claim 8 wherein the measurement of noise data in (d) is performed prior to the prism acquisition in (a).

12. The method of claim 8 wherein the measurement of noise data in (d) is performed after the prism acquisition in (a).

13. The method of claim 8 wherein the measurement of noise data in (d) is performed at one or more time points in between the repetitions of the prism acquisition in (a).

14. The method of claim 8 wherein in (e), receiver coils are combined by using Maximal Ratio Combining in order to maximize the final SNR.

15. The method of claim 8 wherein in (e), the receiver coils are combined by using Selection Combining to maximize the final SNR.

16. The method of claim 1 wherein the motion assessment in (b)(iii) is performed by:
d) smoothing the frames in order to reduce the noise in the frames using a spatial filter;
e) taking a sub-region of the frame, where the size of the sub-region is chosen for the local variation in motion typical in that tissue;
f) windowing the sub-regions;
g) for each pair of two frames, computing a two-dimensional cross-correlation of the sub-regions;
h) determining the position of the maximum value of the computed cross-correlation, giving the local shift in x- and y-position for the sub-region of the pair of frames;
i) repeating steps (g) and (h) while translating the sub-regions across and down the frame to build up a map of the local shift versus position for that pair of frames, termed a shift map;
j) repeating steps (e) to (i) for each pair of frames to generate a series of shift maps of locally estimated shifts.

17. The method of claim 16 wherein the calculation of the two-dimensional cross-correlation is performed in frequency-space, rather than position space, so that the sampling rate of the cross-correlation function in position-space can be varied from the sampling rate of the original data to produce sub-pixel calculations of shifts.

18. The method of claim 16 wherein the locally estimated shifts are compared to a threshold value, and if the local shifts from any of the frames exceed the threshold, the dataset is indicated as having significant motion, so that it may be reacquired by the user while the patient is still within the MRI scanner.

19. The method of claim 16 wherein the locally estimated shifts are displayed to the user as an animation or series of plots so that the user can visualize and assess the local motion.

20. The method of claim 19 wherein the locally estimated shifts for each frame are displayed as a point plotted at the center of the sub-region with a hue/color indicating the direction of the local shift and a value/brightness indicating the magnitude of the shift.

21. In a Magnetic Resonance Imaging (MRI) System, a method for improving the quality of spatial frequency spectra generated from a prism acquisition consisting of echo data that is one or more repetitions of a one-dimensional frequency encoded signal along the length of one or more prism volumes, placed within a sample of a structure to be studied, comprising;
a) gathering a prism acquisition consisting of one or more individual repetitions of echo data from one or more prism volumes using one or more receiver coils in the Magnetic resonance Imaging (MRI) System;
b) correcting for patient motion affecting the quality of the prism acquisition by:
i) transforming the echo data gathered in (a) for each prism volume to calculate the variation of signal versus position, termed the prism profile, for each repetition for each receiver coil;
ii) combining the prism profile from a selection of one or more of the receiver coils to produce a combined prism profile for each prism volume and each repetition;
iii) combining the repetitions gathered into blocks of one or more overlapping or adjacent repetitions to produce a series of frames showing the prism profiles for the set of prisms volumes for each block, and using the change in prism profiles between frames to calculate the patient motion which has occurred during the prism acquisition;
iv) using the calculation of patient motion in (iii) to determine whether the calculated motion is below a threshold value, and if so then calculating the spatial frequency spectra from the prism profiles, and if not then the dataset is discarded and indicated to be re-acquired.

22. The method of claim 21 wherein the estimate of motion in (b)(iii) is used to correct for the motion which has occurred during the prism acquisition by spatially shifting the repetitions of prism profiles relative to one another in (b)(iv) prior to generation of spatial frequency spectra.

23. The method of claim 21 wherein the motion assessment in (b)(iii) is performed by generating plots of the prism profiles for each block, and displaying these as a series of frames, or animation, from which the user can visualize and assess the motion during the prism acquisition.

24. The method of claim 21 wherein the motion assessment in (b)(iii) is performed for one prism volume by generating plots of the prism profile for that prism volume for each block, and displaying each of these frames adjacent to one another to form one representation enabling the motion during the prism acquisition to be visualized.

25. The method of claim 21 wherein in (b)(ii), the receiver coils are combined by:
d) measuring noise data on a set of receiver coils corresponding to the receiver coils used for the prism acquisition in (a);
e) estimating the signal-to-noise ratio (SNR) for each of the receiver coils using the ratio of the prism acquisition echo data acquired in (a) and the noise data acquired in (d) and using the ratio to combine the prism acquisition echo data from receiver coils using diversity combining in order to maximize the final SNR;
f) using the calculation of signal-to-noise ratio for each receiver coil in (b)(ii) to determine whether the prism acquisition has an SNR above a threshold value, and if not then the dataset is discarded and indicated to be re-acquired.

26. The method of claim 25 wherein the measurement of noise data in (d) is performed by blanking the radio frequency amplifiers for each of the receiver coils so that only noise data is gathered.

27. The method of claim 25 wherein the measurement of noise data in (d) is performed by setting the radio frequency transmit voltages to zero so that only noise data is gathered.

28. The method of claim 25 wherein the measurement of noise data in (d) is performed prior to the prism acquisition in (a).

29. The method of claim 25 wherein the measurement of noise data in (d) is performed after the prism acquisition in (a).

30. The method of claim 25 wherein the measurement of noise data in (d) is performed at one or more time points in between the repetitions of the prism acquisition in (a).

31. The method of claim 25 wherein in (e), receiver coils are combined by using Maximal Ratio Combining in order to maximize the final SNR.

32. The method of claim 25 wherein in (e), the receiver coils are combined by using Selection Combining to maximize the final SNR.

33. The method of claim 21 wherein the motion assessment in (b)(iii) is performed by:
d) smoothing the frames in order to reduce the noise in the frames using a spatial filter;
e) taking a sub-region of the frame, where the size of the sub-region is chosen for the local variation in motion typical in that tissue;
f) windowing the sub-regions;
g) for each pair of two frames, computing a two-dimensional cross-correlation of the sub-regions;
h) determining the position of the maximum value of the computed cross-correlation, giving the local shift in x- and y-position for the sub-region of the pair of frames;
i) repeating steps (g) and (h) while translating the sub-regions across and down the frame to build up a map of the local shift versus position for that pair of frames, termed a shift map;
j) repeating steps (e) to (i) for each pair of frames to generate a series of shift maps of locally estimated shifts.

34. The method of claim 33 wherein the calculation of the two-dimensional cross-correlation is performed in frequency-space, rather than position space, so that the sampling rate of the cross-correlation function in position-space can be varied from the sampling rate of the original data to produce sub-pixel calculations of shifts.

35. The method of claim 33 wherein the locally estimated shifts are compared to a threshold value, and if the local shifts from any of the frames exceed the threshold, the dataset is indicated as having significant motion, so that it may be reacquired by the user while the patient is still within the MRI scanner.

36. The method of claim 33 wherein the locally estimated shifts are displayed to the user as an animation or series of plots so that the user can visualize and assess the local motion.

37. The method of claim 36 wherein the locally estimated shifts for each frame are displayed as a point plotted at the center of the sub-region with a hue/color indicating the direction of the local shift and a value/brightness indicating the magnitude of the shift.

38. In a Magnetic Resonance Imaging (MRI) System, a method for improving the quality of spatial frequency spectra generated from a prism acquisition consisting of echo data that is one or more repetitions of a one-dimensional frequency encoded signal along the length of one or more prism volumes, placed within a sample of a structure to be studied, comprising;
a) gathering a prism acquisition consisting of one or more individual repetitions of echo data from one or more prism volumes using one or more receiver coils in the Magnetic resonance Imaging (MRI) System;
b) correcting for patient motion affecting the quality of the prism acquisition by:
i) during the same study, acquiring a reference image of the sample of the structure to be studied, either prior to or following the prism acquisition in (a), which is co-located with the prism acquisition in (a);
ii) specifying one or more regions of the sample of the structure to be studied on the reference image acquired in (b)(i);
iii) using a three-dimensional coordinate transform to translate the points specifying the regions in (b)(ii) from locations in the reference image to corresponding locations in the prism volumes;
iv) transforming the echo data gathered in (a) to calculate the signal versus position along each of the prism volumes for each repetition for each receiver coil, and for each prism volume to obtain the respective prism profile;
v) smoothing the prism profiles by application of a spatial filter in order to reduce the noise;
vi) calculating the presence of anatomical features in the prism profiles by generating a map of the prevalence of sharp boundaries and features present, termed the feature map;
vii) using the points calculated in (iii) to perform a segmentation of the feature map calculated in (vi) within the specified region;
viii) calculating the estimated shift of the segmented feature map in (vii) which minimizes the presence of anatomical features present in the segmented prism volumes, and using the estimated shift to spatially shift the segmented prism volumes to correct for motion, prior to generation of spatial frequency spectra from the prism acquisition echo data.

39. The method of claim 38 wherein in (b), the calculation of the presence of anatomical features in (b)(vi) is performed by calculating a numerical gradient of the profile.

40. The method of claim 38 wherein in (b), the calculation of the presence of anatomical features in (b)(vi) is performed by using a Canny edge detection algorithm.

41. The method of claim 38 wherein in (b), the calculation of the presence of anatomical features in (b)(vi) is performed by application of a Sobel filter.
